(19) United States
(12) Patent Application Publication
(10) Pub. No.: US 2025/0361619 A1
(43) Pub. Date: Nov. 27, 2025

(54) Automated chemical vapor deposition apparatus capable of achieving atomic precision manufacturing

(71) Applicant: Zhejiang University, Hangzhou (CN)

(72) Inventors: Rong XIANG, Hangzhou (CN); Yige ZHENG, Hangzhou (CN); Lingfeng WANG, Hangzhou (CN); Yicheng MA, Hangzhou (CN)

(21) Appl. No.: 19/294,606

(22) Filed: Aug. 8, 2025

Related U.S. Application Data
(63) Continuation of application No. PCT/CN2024/106896, filed on Jul. 23, 2024.

(30) Foreign Application Priority Data
Jan. 30, 2024 (CN) 202410122778.3

(51) Int. Cl. C23C 16/52

(52) U.S. Cl. CPC C23C 16/52

(57) ABSTRACT

An automated chemical vapor deposition apparatus capable of achieving atomic precision manufacturing integrates a pressure system, a temperature system, and a flow rate system, thereby achieving fully automated control throughout the chemical vapor deposition process. In terms of pressure control, an empirical valve opening angle is introduced to rapidly approach the target pressure, greatly improving response time. Moreover, a discontinuous-angle control algorithm is designed to achieve higher control precision even encountered in the chemical vapor deposition process. The apparatus is also provided with an in-situ characterization system, which can achieve real-time monitoring of the sample deposition in the chemical vapor deposition process through corresponding devices. Moreover, the present disclosure designs a furnace chamber travel track. After the deposition process is completed, the furnace chamber can be moved to making a heating zone fully exposed to air, thereby maximizing heat dissipation efficiency and improving overall production efficiency.

### TECHNICAL FIELD

The present disclosure relates to the technical field of atomic layer deposition, and in particular to an automated chemical vapor deposition (CVD) apparatus capable of achieving atomic precision manufacturing.

### BACKGROUND

With the continuous advancement of modern scientific research, the precision of processing techniques and manufacturing technology has been steadily improving. Mechanical engineering is increasingly integrating and intersecting with disciplines such as chemistry, physics, and materials science, giving birth to a new frontier area known as “atomic and close-to-atomic scale manufacturing.”

Atomic and close-to-atomic scale manufacturing refers to a process of manufacturing and processing performed at or near an atomic scale. Atomic layer deposition (ALD) technology is a method that enables the layer-by-layer growth of thin films on a surface of materials using a chemical reaction, and can achieve highly precise control over film thickness and material composition. Therefore, it is widely applied in fields such as microelectronics, optoelectronics, and touch screens.

In order to achieve precise control over a deposited sample, the corresponding chemical vapor deposition (CVD) equipment that is provided with highly accurate temperature, pressure, and flow control systems is required. However, most of the CVD systems currently available in China are assembled using instruments and components from different manufacturers. As a result, the parameters of each system require manual adjustment and intervention, resulting in a low level of automation. Moreover, due to reliance on manual operation, control precision is low and insufficient to meet the rigorous requirements of atomic layer deposition.

### SUMMARY

In order to solve the existing problems, the present disclosure provides an automated chemical vapor deposition (CVD) apparatus capable of achieving atomic precision manufacturing, which includes a pressure system, a temperature system, a flow rate system, and a control system; where the pressure system, the temperature system, and the flow rate system are all connected to the control system; and the control system performs fully automated control of the apparatus based on real-time feedback data from the pressure system, the temperature system, and the flow rate system.

Optionally, the pressure system includes a valve, a stepper motor, and a pressure sensor disposed within the quartz tube of the CVD apparatus, and the pressure sensor is configured to acquire a pressure value within the quartz tube in real time, such that the control system can adjust a valve opening angle of an exhaust pipeline in real time according to the acquired pressure value to achieve a target pressure, and the target pressure is the pressure value required at each stage of the thin film deposition process; the valve is connected to the exhaust pipeline, the stepper motor is configured to drive the valve to open or close at a given step angle, and a pressure can be directly controlled by adjusting an opening angle of the valve in the vacuum pipeline under the condition of a constant gas flow rate; and when adjusting the valve opening angle of the exhaust pipeline in real time, the control system automated ally controls a pressure either a periodic discontinuous-angle control algorithm or a continuous-angle control algorithm, depending on a relationship between the pressure value and the preset pressure threshold.

Optionally, the control system can adjust a valve opening angle of an exhaust pipeline in real time according to the acquired pressure value to achieve a target pressure, which includes:

the control system first adjusts the valve to an empirical opening angle corresponding to the target pressure according to an angle-pressure empirical curve; and the angle-pressure empirical curve is a curve of changes in pressure inside the quartz tube with the valve opening angle under fixed flow rate and temperature conditions.

A method for acquiring the angle-pressure empirical curve includes: maintaining a constant temperature, and determining a pressure changes with the changes in the butterfly valve opening angle under a constant gas flow rate.

A method for acquiring the angle-rate empirical curve includes: maintaining a constant temperature, setting a sampling cycle, and determining changes in the pressure change rate in the sampling cycle as the butterfly valve opening angle changes under a constant gas flow rate.

The butterfly valve opening angle corresponding to the target pressure required at each stage of the film deposition process is determined based on the angle-pressure empirical curve, that is, the empirical opening angle. The buttery value is quickly opened to the empirical opening angle, to enable the actual pressure to quickly approach the target pressure.

By comparing the pressure value with the preset pressure threshold, when the pressure value is greater than or equal to the preset pressure threshold, a periodic discontinuous-angle control algorithm is used for automated pressure control; otherwise, a continuous-angle control algorithm is used for automated pressure control.

In the actual deposition process, when the pressure reaches a specific value Po, time required to increase the pressure to a given value is much longer than time to reduce the pressure to the same given value, and P_{θ} is defined as the pressure threshold. Different control algorithms are applied for pressure values greater than and less than the pressure threshold.

Optionally, logic of the periodic discontinuous-angle control algorithm is as follows:

a pressure sampling interval ΔT and a pressure change rate threshold ΔP_{θ} are defined; the pressure change rate threshold ΔP_{θ} is determined according to an angle-rate empirical curve; the angle-rate empirical curve is a curve of changes in pressure change rate inside the quartz tube with the valve opening angle under fixed flow rate and temperature conditions; and it is observed from change trend in the angle-rate empirical curve that, as the butterfly valve opening angle increases, the pressure change rate gradually increases to a peak value and then decreases, that is, the pressure change rate has a maximum value.
S1: obtaining the pressure change rate ΔP over the pressure sampling interval ΔT;
S2: determining whether an absolute value of the pressure change rate ΔP exceeds the set pressure change rate threshold ΔP_{θ};
S2.1: determining a step angle and a direction of the valve according to a degree to which the absolute value of the pressure change rate exceeds the set pressure change rate threshold, and positive and negative values of the pressure change rate ΔP when the absolute value of the pressure change rate ΔP exceeds the set pressure change rate threshold ΔP_{θ}; and

the degree to which the absolute value of the pressure change rate exceeds the set pressure change rate threshold may be divided into various levels, for example:
1) when the absolute value of the pressure change rate ΔP exceeds 50% of the ΔPₘₐₓ and ΔP is a positive value, the butterfly valve steps forward by the step angle α₁;
2) when the absolute value of the pressure change rate ΔP exceeds 70% of the ΔPₘₐₓ and ΔP is a positive value, the butterfly valve steps forward by the step angle α₂;
3) when the absolute value of the pressure change rate ΔP exceeds 80% of the ΔPₘₐₓ and ΔP is a positive value, the butterfly valve steps forward by the step angle α₃; the aforesaid step angles satisfy the conditions: α₁<α₂<α₃.

In the above three cases, when the pressure change rate ΔP is a negative value, the butterfly valve steps in a reverse direction by the corresponding step angle; where the forward step of the butterfly valve is open, and the reverse step is closed.
S2.2: further acquiring a current pressure value P and determining magnitudes of the current pressure value P and the target pressure and positive or negative pressure change rate ΔP when the absolute value of the pressure change rate ΔP does not exceed the set pressure change rate threshold ΔP_{θ}; and determining the step angle and the direction of the valve accordingly:
1) when the current pressure value P is less than the target pressure, and the pressure change rate ΔP is a positive value, the buttery valve maintains the current angle or steps in a reverse direction by a step angle Δ₄;
2) when the current pressure value P is less than the target pressure, and the pressure change rate ΔP is a positive value, the buttery valve steps in a reverse direction by a step angle

3) when the current pressure value P is greater than the target pressure, and the pressure change rate ΔP is a negative value, the buttery valve steps in a reverse direction by a step angle α₄;

4) when the current pressure value P is greater than the target pressure, and the pressure change rate ΔP is a negative value, the buttery valve maintains the current angle or steps in a reverse direction by a step angle α₅;

where α₄<α₅, and α₄<<<α₁, α₅<<<α₁.
S3. reading a pressure inside the quartz tube after the valve opening angle is adjusted, and calculating a difference with the target pressure, and determining whether the difference falls within an error range; the current valve opening angle is maintained when the difference falls within the error range; or a pressure change rate in a next sampling cycle is sampled when the difference fails to fall within the error range; and repeating the above process.

Optionally, the temperature system includes a temperature sensor, where the temperature sensor is disposed on an outer wall of the quartz tube at a position corresponding to the deposited sample; the temperature sensor is configured to obtain a temperature at the position of the deposited sample in real time; and the control system is configured to adjust heating power and heating duration according to the real-time temperature feedback from the temperature sensor, to ensure that a temperature inside the quartz tube reaches a target temperature value.

Optionally, the apparatus includes an in-situ characterization system, where the in-situ characterization system includes an absorption spectrum detection device, and a spectrum movement and optical path calibration device; and the absorption spectrum detection device enables online in-situ characterization of the deposited sample; and

the absorption spectrum detection device includes a light source, a light source emitting module, a light source receiving module, and a spectrometer connected to the light source receiving module; and

the spectrum movement and optical path calibration device includes two linear guide rails, and the light source emitting module and the light source receiving module are respectively mounted on the two linear guide rails; and the light source emitting module and the light source receiving module are moved along the linear guide rails to achieve online in-situ characterization of samples at any position in a quartz tube.

The tubular CVD device includes a furnace chamber, a quartz tube, and a quartz boat disposed within the quartz tube for holding the deposited sample. In order to allow the light emitted from the light source emitting module to pass through the furnace chamber and achieve online in-situ characterization of samples at any position in a quartz tube, the furnace chamber is provided with two symmetrical optical access slots parallel to the quartz tube, the two optical access slots are symmetrically arranged with respect to an axial centerline of the quartz tube, and the two linear guide rails of the spectrum movement and optical path calibration device are respectively located at positions outside the furnace chamber corresponding to the two optical access slots, such that the light source emitting module and the light source receiving module can move linearly in an axial direction of the quartz tube to achieve online in-situ detection of samples at any position in the quartz tube; and the light emitted from the light source emitting module passes through the optical access slots, traverses the quartz tube and the deposited sample therein, and then reaches the light source receiving module, and the received light is then analyzed by the spectrometer to achieve in-situ detection of the deposited sample; and a width of the optical access slot is set such that the light emitted from the light source emitting module and the light received by the light source receiving module can completely pass through.

Optionally, the spectrum movement and optical path calibration device further includes four stepper motors and is provided with a four-axis automated optical calibration system. The four stepper motors are respectively recorded as a first horizontal stepper motor, a first vertical stepper motor, a second horizontal stepper motor, and a second vertical stepper motor; where the first horizontal stepper motor and the first vertical stepper motor achieve positioning of the light source emitting module in a horizontal plane by driving a ball screw and a guide rail mechanism, and the second horizontal stepper motor and the second vertical stepper motor are configured to control the rotation of the light source emitting module in horizontal and vertical planes, respectively.

Optionally, the four-axis optical path automated calibration system employs a microcontroller or a programmable logic controller (PLC) to control the stepper motors. A rotation speed of each stepper motor can be controlled by setting its pulse-width modulation (PWM) wave.

By comparing an intensity of the returned light, an optical path can be fine-tuned to maximize the intensity of the received light, thereby facilitating subsequent spectral analysis.

Optionally, the light source is a white light source with a continuous spectrum, a wavelength at least covers a range of 200-1050 nm; where an ultraviolet band luminous flux with a wavelength range of 250-400 nm is greater than 10 mW/mm²·sr·nm; and the light source offers strong collimation, with light spots focused within a circle with a diameter of 1 mm at a distance of 0.5 m.

Optionally, the apparatus is further provided with a furnace chamber travel track configured to enable the movement of the furnace chamber; and after the deposition process is completed, the furnace chamber can be moved to making a heating zone fully exposed to air, thereby maximizing heat dissipation efficiency and improving overall production efficiency.

Optionally, the flow rate system includes a flow meter, and the control system controls the flow meter according to preset flow rate parameters to achieve precise flow rate control.

Optionally, the apparatus further includes a touch screen, through which the technician can set the corresponding parameters.

The present disclosure has the beneficial effects:

By providing the CVD apparatus integrating a pressure system, a temperature system, and a flow rate system, the present disclosure achieves fully automated control throughout the chemical vapor deposition process. Specifically, in terms of pressure control, an empirical valve opening angle is introduced to rapidly approach the target pressure, greatly improving response time. Moreover, a discontinuous-angle control algorithm is designed to achieve higher control precision even encountered in the chemical vapor deposition process. In terms of temperature control, a PID control algorithm is adopted to control the on/off state of a solid-state relay, thereby achieving precise temperature control. Further, the apparatus is also provided with an in-situ characterization system, which can achieve real-time monitoring of the sample deposition in the chemical vapor deposition process through corresponding devices. Combined with changes in system temperature and pressure, the law of changes in the sample or reaction system with environmental changes such as temperature and pressure can be further acquired, thereby determining the optimal deposition conditions. Moreover, the present disclosure designs a furnace chamber travel track. After the deposition process is completed, the furnace chamber can be moved to making a heating zone fully exposed to air, thereby maximizing heat dissipation efficiency and improving overall production efficiency.

### BRIEF DESCRIPTION OF THE DRAWINGS

In order to more clearly illustrate the technical solution in the embodiments of the present disclosure, the accompanying drawings required to be used in the description of the embodiments are simply introduced below, and obviously, the accompanying drawings described below are only some embodiments of the present disclosure, such that for those of ordinary skill in the art, other drawings may further be derived from these drawings without making inventive efforts.

FIG. 1 is a schematic diagram showing a positional relationship between a furnace chamber travel track and a furnace chamber in a CVD apparatus according to an embodiment of the present disclosure, and in the figure: 1. Furnace chamber; 2. quartz tube, and 12. furnace chamber travel track.

FIG. 2 is a flowchart of a method for automated ally controlling pressure by a control system according to an embodiment of the present disclosure.

FIG. 3 shows an angle-pressure empirical curve corresponding to a gas flow rate at 0 at room temperature (25°° C.).

FIG. 4 shows an angle-rate empirical curve corresponding to a gas flow rate at 0 at room temperature (25° C.).

FIG. 5 is a schematic diagram of composition of an in-situ characterization system in a CVD apparatus according to an embodiment of the present disclosure, and in the figure: 1. furnace chamber; 2. quartz tube; 3. quartz boat; 4. deposited sample; 5. optical access slot; 6. light source; 7. light source emitting module; 8. light source receiving module; 9. spectrometer; 10. linear guide rail; and 11. stepper motor.

FIG. 6 is a perspective schematic diagram of a four-axis optical path automated calibration system of an in-situ characterization system in a CVD apparatus according to an embodiment of the present disclosure, and in the figure: 1101. first horizontal stepper motor; 1102. first vertical stepper motor; 1103. second horizontal stepper motor; and 1104. second vertical stepper motor.

### DETAILED DESCRIPTIONS OF THE EMBODIMENTS

In order to make the objects, technical solutions, and advantages of the present disclosure clearer, the embodiments of the present disclosure will be further described below in detail in conjunction with the accompanying drawings.

### Embodiment 1

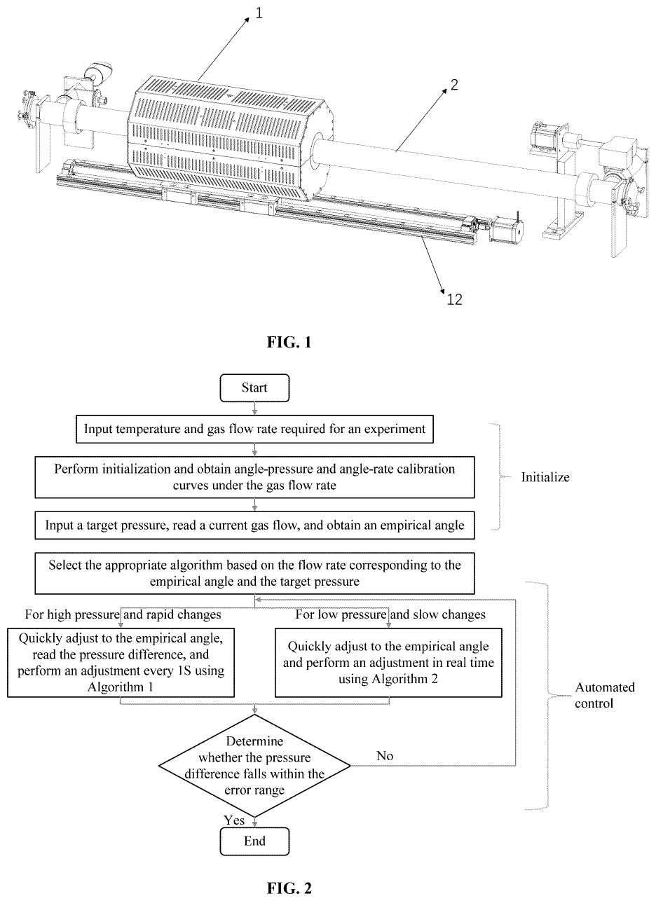

This embodiment provides an automated chemical vapor deposition (CVD) apparatus capable of achieving atomic precision manufacturing, including a pressure system, a temperature system, a flow rate system, and a control system; where the pressure system, the temperature system, and the flow rate system are all connected to the control system; and the control system performs fully automated control of the apparatus based on real-time feedback data from the pressure system, the temperature system, and the flow rate system. The apparatus is provided with a display screen integrated with touch sensing functionality, allowing a technician to directly input corresponding deposition parameters, and the control system can then complete the entire deposition process according to the preset parameters. Moreover, in order to accelerate cooling after the deposition is completed, the present disclosure designs a furnace chamber travel track 12, as shown in FIG. 1. When waiting for heat dissipation, a furnace chamber is moved to making a heating zone of a quartz tube 2 fully exposed to air, thereby maximizing heat dissipation efficiency and improving overall production efficiency.

Each component will be described as follows:

(1) the pressure system includes a valve, a stepper motor, and a pressure sensor disposed within the quartz tube of the CVD apparatus, and the pressure sensor is configured to acquire a pressure value within the quartz tube in real time, such that the control system can adjust a valve opening angle of an exhaust pipeline in real time according to the acquired pressure value to achieve a target pressure; the valve is connected to the exhaust pipeline, the stepper motor is configured to drive the valve to open or close at a given step angle; when adjusting the valve opening angle of the exhaust pipeline in real time, the control system automated ally controls a pressure either a periodic discontinuous-angle control algorithm or a continuous-angle control algorithm, depending on a relationship between the pressure value and the preset pressure threshold. The specific control process is illustrated in FIG. 2, Algorithm 1 in FIG. 2 is the periodic discontinuous-angle control algorithm, and Algorithm 2 is the continuous-angle control algorithm.

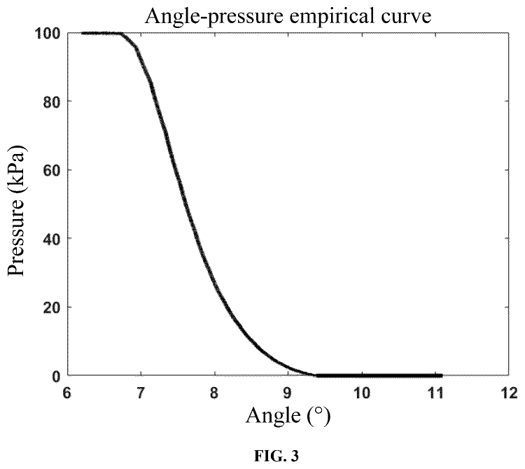

when adjusting the valve opening angle of the exhaust pipeline in real time, the control system first adjusts the valve to an empirical opening angle corresponding to the target pressure according to an angle-pressure empirical curve; and the angle-pressure empirical curve is a curve of changes in pressure inside the quartz tube with the valve opening angle under fixed flow rate and temperature conditions. Angle-pressure empirical curves under different temperature and flow conditions can be obtained in advance. In a specific deposition process, only a current gas flow and a temperature need to be measured to determine a valve opening angle corresponding to the target pressure, that is, the empirical opening angle. FIG. 3 shows the angle-pressure empirical curve corresponding to a gas flow rate at 0 at room temperature (25° C.).

Considering that the pressure inside the quartz tube varies greatly in the actual deposition process, ranging from vacuum to atmospheric pressure, and when the pressure reaches a specific value, time required to increase the pressure to a given value P_{θ} is much longer than time to reduce the pressure to the same given value. For a pressure greater than P_{θ}, a pressure control scheme different from that less than P_{θ} needs to be adopted. Therefore, the present disclosure presets a pressure threshold P_{θ} (a value of the pressure threshold P_{θ} may be determined by the technician, such as P_{θ}=20 kPa, and automated control over the pressure is performed using either the periodic discontinuous-angle control algorithm or the continuous-angle control algorithm according to the relationship between the pressure value and the preset pressure threshold P_{θ}. Specifically:

When the pressure value is greater than or equal to the preset pressure threshold, a periodic discontinuous-angle control algorithm is used for automated pressure control, otherwise, the continuous-angle control algorithm is used for automated pressure control. Specifically, the continuous-angle control algorithm is a proportional-integral-derivative (PID) control algorithm, which is a relatively mature algorithm in the industrial field. For the detailed description of the algorithm, reference can be made to the Chinese Patent CN112695297A (titled Chamber Pressure Control Method in Semiconductor Process) and CN116931610A (titled Rapid-Response Method and Device for Pressure Control), which will not be elaborated in detail herein. Logic of the periodic discontinuous-angle control algorithm is as follows:

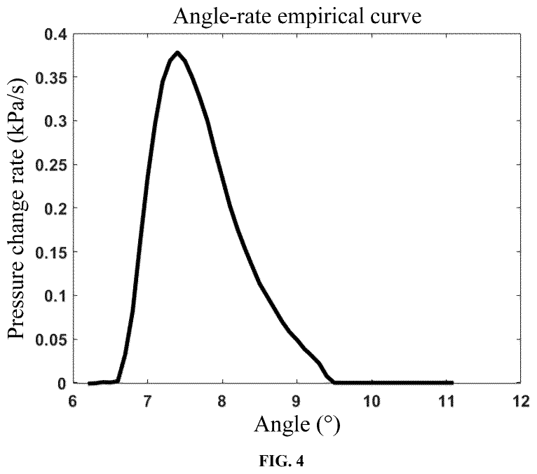

a pressure sampling interval ΔT and a pressure change rate threshold ΔP_{θ} are set; the pressure change rate threshold ΔP_{θ} is determined according to an angle-rate empirical curve; the angle-rate empirical curve is a curve of changes in pressure change rate inside the quartz tube with the valve opening angle under fixed flow rate and temperature conditions; from the actual angle-rate empirical curve, it is observed that the pressure change rate has a maximum value ΔPₘₐₓ with an increase in the valve opening angle, therefore, the pressure change rate threshold ΔPₑ may be set as ΔP_{θ}=K*ΔPₘₐₓ, K=0.5˜0.8, a specific value is determined by the technician. FIG. 4 shows the angle-rate empirical curve corresponding to a gas flow rate at 0 at room temperature (25° C.). It can be seen that the maximum value of the pressure change rate is ΔPₘₐₓ=0.38 kPa/s when the gas flow rate is 0 at 25° C.

S1: obtaining the pressure change rate ΔP over the pressure sampling interval ΔT;

S2: determining whether an absolute value of the pressure change rate ΔP exceeds the set pressure change rate threshold ΔP_{θ};

S2.1: determining a step angle and a direction of the valve according to a degree to which the absolute value of the pressure change rate exceeds the set pressure change rate threshold, and positive and negative values of the pressure change rate ΔP when the absolute value of the pressure change rate ΔP exceeds the set pressure change rate threshold ΔP_{θ}; specifically, the degree to which the absolute value of the pressure change rate exceeds the set pressure change rate threshold may be divided into various levels, for example:
1) when the absolute value of the pressure change rate ΔP exceeds 50% of the ΔPₘₐₓ and ΔP is a positive value, the butterfly valve steps forward by a step angle α₁;
2) when the absolute value of the pressure change rate ΔP exceeds 70% of the ΔPₘₐₓ and ΔP is a positive value, the butterfly valve steps forward by a step angle α₂;
3) when the absolute value of the pressure change rate ΔP exceeds 80% of the ΔPₘₐₓ and ΔP is a positive value, the butterfly valve steps forward by a step angle α₃; and the aforesaid step angles satisfy the conditions: α₁<α₂<α₃.

In the above three cases, when the pressure change rate ΔP is a negative value, the butterfly valve steps in a reverse direction by the corresponding step angle; where the forward step of the butterfly valve is open, and the reverse step is closed.

In one implementation mode, α₁=0.05°, α₂=0.1°, and α₃=0.15°.
S2.2: further acquiring a current pressure value P and determining magnitudes of the current pressure value P and the target pressure and positive or negative pressure change rate ΔP when the absolute value of the pressure change rate ΔP does not exceed the set pressure change rate threshold ΔP_{θ}; and determining the step angle and the direction of the valve accordingly; specifically:
1) when the current pressure value P is less than the target pressure, and the pressure change rate ΔP is a positive value, the buttery valve maintains the current angle or steps in a reverse direction by a step angle α₄;
2) when the current pressure value P is less than the target pressure, and the pressure change rate ΔP is a positive value, the buttery valve steps in a reverse direction by a step angle α₅;
3) when the current pressure value P is greater than the target pressure, and the pressure change rate ΔP is a negative value, the buttery valve steps in a reverse direction by a step angle α₄;
4) when the current pressure value P is greater than the target pressure, and the pressure change rate ΔP is a negative value, the buttery valve maintains the current angle or steps in a reverse direction by a step angle a₅;

where α₄<α₅, and α₄<<<α₁, α₅<<<α₁.

In one implementation mode, α₄=0.001°, α₅=0.002°
S3. reading a pressure inside the quartz tube after the above adjustments, and calculating a difference with the target pressure, and determining whether the difference falls within an error range; the current valve opening angle is maintained when the difference falls within the error range; or a pressure change rate in a next sampling cycle is sampled when the difference fails to fall within the error range; and repeating the above process.

(2) The temperature system includes a temperature sensor, where the temperature sensor is disposed on an outer wall of the quartz tube at a position corresponding to the deposited sample; the temperature sensor is configured to obtain a temperature at the position of the deposited sample in real time; and the control system is configured to adjust heating power and heating duration according to the real-time temperature feedback from the temperature sensor, to ensure that a temperature inside the quartz tube reaches a target temperature value.

(3) The flow rate system includes a flow meter, and the control system controls the flow meter according to preset flow rate parameters to achieve precise flow rate control.

(4) In order to achieve real-time monitoring of the chemical vapor deposition process for atomic-level material manufacturing, the apparatus provided in the present disclosure further includes an in-situ characterization system, the in-situ characterization system includes an absorption spectrum detection device, and a spectrum movement and optical path calibration device; as shown in FIG. 5, the absorption spectrum detection device includes a light source 6, a light source emitting module 7, a light source receiving module 8, and a spectrometer 9 connected to the light source receiving module 8; the spectrum movement and optical path calibration device includes two linear guide rails 10 and corresponding stepper motors 11, and the light source emitting module 7 and the light source receiving module 8 are respectively mounted on the two linear guide rails 10; and the tubular CVD device includes a furnace chamber 1, a quartz tube 2, and a quartz boat 3 disposed within the quartz tube 2 for holding the deposited sample 4; the furnace chamber 1 is provided with two symmetrical optical access slots 5 parallel to the quartz tube 2, the two optical access slots 5 are symmetrically arranged with respect to an axial centerline of the quartz tube 2, and the two linear guide rails 10 of the spectrum movement and optical path calibration device are respectively located at positions outside the furnace chamber 1 corresponding to the two optical access slots 5, such that the light source emitting module 7 and the light source receiving module 8 can move linearly in an axial direction of the quartz tube 2; and light emitted from the light source emitting module 7 passes through the optical access slots 5, traverses the quartz tube 2 and the deposited sample 4 therein, and then reaches the light source receiving module 8, and the received light is then analyzed by the spectrometer 9 to achieve in-situ detection of the deposited sample 4.

A length of the optical access slots 5 may be determined according to actual conditions, and a width thereof is set such that the light emitted from the light source emitting module 7 and the light received by the light source receiving module 8 can completely pass through.

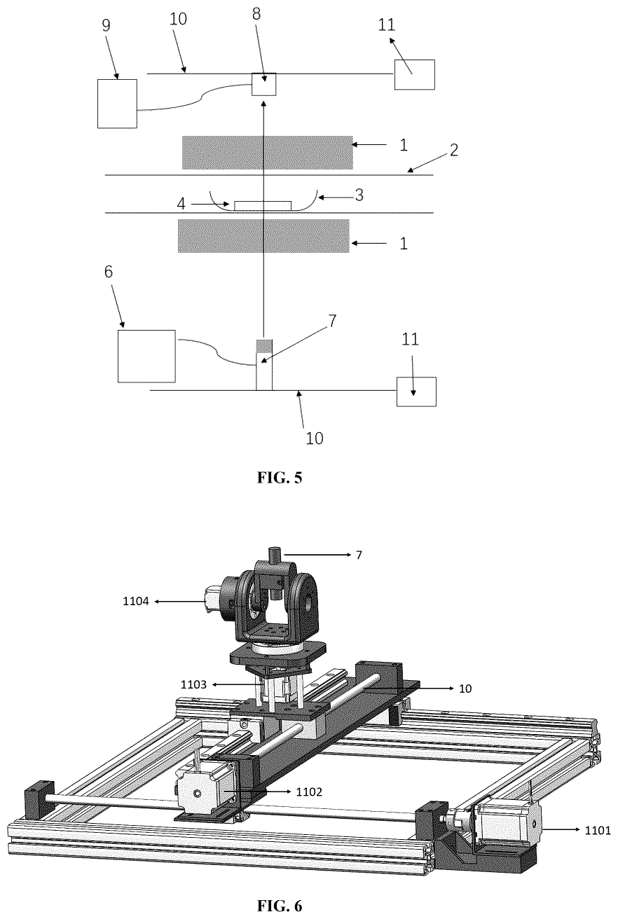

In order to ensure that the light emitted from the light source emitting module 7 can be precisely received by the light source receiving module 8, the present disclosure provides a four-axis optical path calibration system, which achieves optical alignment between the light source emitting module 7 and the light source receiving module 8 by means of four stepper motors 11; as shown in FIG. 6, a first horizontal stepper motor 1101 and a first vertical stepper motor 1102 are used for coarse adjustment, while a second horizontal stepper motor 1104 and a second vertical stepper motor 1103 are used for fine adjustment. The first horizontal stepper motor 1101 and the first vertical stepper motor 1102 achieve positioning of the light source emitting module in a horizontal plane by driving a ball screw and a guide rail mechanism, and the second horizontal stepper motor 1104 and the second vertical stepper motor 1103 are configured to control the rotation of the light source emitting module 7 in horizontal and vertical planes, respectively. The combination of the four stepper motors enables precise calibration of the light source. The four stepper motors are controlled by an STM32 microcontroller or a programmable logic controller (PLC). A rotation speed of each stepper motor can be controlled by setting its pulse-width modulation (PWM) wave. By comparing an intensity of the returned light, an optical path can be fine-tuned to maximize the intensity of the received light, thereby facilitating subsequent spectral analysis.

The light source 6 meets the following conditions:
1) emitting a continuous spectrum covering a wavelength range of 200-2000 nm;
2) providing strong enough overall light intensity, especially in an ultraviolet band of 200-400 nm, with a spectral radiance greater than 10 mW/mm²·sr·nm; and
3) offering strong collimation, with light spots focused within a circle with a diameter of 1 mm at a distance of 0.5 m.

Considering the high-temperature environment of deposition process, the furnace chamber glows red, which will have an impact on the light source signal. Therefore, direct analysis based solely on the spectral signal may lead to some errors. To solve this problem, the present disclosure also obtains a temperature gradient compensation spectrum in advance, and performs corresponding compensation on the acquired spectrum before analysis, thereby achieving more accurate analytical results. Specifically:

Step 1: placing no sample to enable the optical path to pass through the quartz tube and the quartz boat to reach the light source receiving module 8 (the spectrometer detector), acquiring a spectrum and recording it as an initial spectrum.

Step 2: gradually raising a temperature to 900° C., taking a spectrum every ΔT from 100° C., subtracting the initial spectrum to acquire a red-light compensation spectrum under different temperature gradients, where a specific value of ΔT may be determined by the technician according to actual conditions, such as ΔT=10° C. or ΔT=25° C.

Subsequently, a real-time spectrum acquired at a given temperature during the deposition process is subtracted by the corresponding red-light compensation spectrum to obtain a more accurate absorption spectrum, which is taken as a final spectrum.

When analyzing the material based on absorption spectrum, an absorbance of the material is calculated using the following formula:

Absorbance=log₁₀(Incident light intensity/Transmitted light intensity)

where the incident light intensity refers to an intensity of light emitted by the light source emitting device 7; and the transmitted light intensity refers to an intensity of light received by the light source receiving module 8.

For example:

Before the sample is placed, the light passes through the quartz boat and the quartz tube. No red-light emission occurs under room temperature conditions (25° C.), and the transmitted light intensity at this stage is recorded as L1;

After the sample is placed, the light passes through the quartz tube, the quartz boat, and the sample in the experimental conditions, red-light emission occurs at 800° C., and a transmitted light intensity at this stage is recorded as L2. Let a light intensity of the red-light compensation spectrum at 800° C. be L3, then an absorbance (measured value) without compensation is A=lg(L1/L2), and an actual value (true value) A′=lg(L1/(L2−L3)). Therefore, a compensation value of the red-light compensation spectrum corresponding to 800° C. is Δ₈₀₀=A′−A=lg(L2/(L2−L3)).

The above method is used to obtain the compensation values Δ₁, Δ₂, Δ₃, . . . and Δₙ corresponding to the red-light compensation spectra at every ΔT from 100° C.

During the subsequent deposition process, when the deposition temperature is set to 800° C., the obtained spectrum needs to subtract the red-light compensation spectrum Δ₈₀₀ corresponding to 800° C. to obtain a final spectrum, and analysis is performed according to the final spectrum.

Step 3: analyzing the deposition of the deposition process according to the final spectrum.

Since the light source emitting module 7 and the light source receiving module 8 are respectively mounted on the two linear guide rails 10, and an axial length of the optical access slot on the furnace chamber allows the light to reach any position inside the quartz tube 2, a sample at any position within the quartz tube 2 can be monitored in real time by the light source emitting module 7 and the light source receiving module 8 to obtain the deposition of the sample.

Existing in-situ technologies all involve in-situ characterization of a single-point position. In contrast, the present disclosure realizes position-variable in-situ characterization inside the quartz tube by synchronously moving the white-light source emitting module 7 and the light source receiving module 8. This innovation plays a significant role in exploring the growth window of new materials.

In many CVD processes, once the parameters such as temperature, pressure, and carrier gas flow rate are determined, a material growth will occur at given positions, which are usually referred to as growth windows. In conventional experimental processes, it is necessary to perform experiments repeatedly at different positions, followed by offline characterization. Several or even dozens of experiments are required to roughly determine the growth windows thereof, making the processes cumbersome and time-consuming. The system and method provided in the present disclosure enable flexible movement during the experiments, and the growth windows can be determined by characterizing the material growth conditions at different positions, making it possible to quickly obtain better deposition results.

The present disclosure provides a CVD apparatus integrating a pressure system, a temperature system, and a flow rate system, thereby achieving fully automated control throughout the chemical vapor deposition process. Specifically, in terms of pressure control, an empirical valve opening angle is introduced to rapidly approach the target pressure, greatly improving response time. Moreover, a discontinuous-angle control algorithm is designed to achieve higher control precision even encountered in the chemical vapor deposition process. In terms of temperature control, a PID control algorithm is adopted to control the on/off state of a solid-state relay, thereby achieving precise temperature control. Further, the apparatus is also provided with an in-situ characterization system, which can achieve real-time monitoring of the sample deposition in the chemical vapor deposition process through corresponding devices. Combined with changes in system temperature and pressure, the law of changes in the sample or reaction system with environmental changes such as temperature and pressure can be further acquired, thereby determining the optimal deposition conditions. Moreover, the present disclosure designs a furnace chamber travel track. After the deposition process is completed, the furnace chamber can be moved to making a heating zone fully exposed to air, thereby maximizing heat dissipation efficiency and improving overall production efficiency.

Some of the steps in the embodiments of the present disclosure may be implemented using software, and the corresponding software programs can be stored on a readable storage medium, such as an optical disk or a hard disk.

What is described above is merely preferred embodiments of the present disclosure, and is not intended to limit the present disclosure. Any modifications, equivalent replacements and improvements, etc. made within the spirit and principle of the present disclosure should fall within the scope of protection of the present disclosure.

What is claimed is:

1. An automated chemical vapor deposition (CVD) apparatus capable of achieving atomic precision manufacturing, comprising a pressure system, a temperature system, a flow rate system, and a control system; wherein the pressure system, the temperature system, and the flow rate system are all connected to the control system; and the control system is configured to perform fully automated control of the apparatus based on real-time feedback data from the pressure system, the temperature system, and the flow rate system;
the pressure system comprises a valve, a stepper motor, and a pressure sensor disposed within a quartz tube of the CVD apparatus, wherein the pressure sensor is configured to acquire a pressure value within the quartz tube in real time, such that the control system is capable of adjusting a valve opening angle of an exhaust pipeline in real time according to the acquired pressure value to achieve a target pressure; the valve is connected to the exhaust pipeline, and the stepper motor is configured to drive the valve to open or close at a given step angle; and when adjusting a valve opening angle of an exhaust pipeline in real time, the control system is configured to perform automated control over a pressure using either a periodic discontinuous-angle control algorithm or a continuous-angle control algorithm according to a relationship between the pressure value and a preset pressure threshold;
the step that the control system is capable of adjusting a valve opening angle of an exhaust pipeline in real time according to the acquired pressure value to achieve a target pressure comprises:
adjusting the valve to an empirical opening angle of the target pressure according to an angle-pressure empirical curve; wherein the angle-pressure empirical curve is a curve of changes in pressure inside the quartz tube with the valve opening angle under fixed flow rate and temperature conditions; and
comparing the pressure value with the preset pressure threshold; and when the pressure value is greater than or equal to the preset pressure threshold, a periodic discontinuous-angle control algorithm is configured for automated pressure control; or when the pressure value is less than the preset pressure threshold, a continuous-angle control algorithm is configured for automated pressure control; wherein
logic of the periodic discontinuous-angle control algorithm is as follows:
a pressure sampling interval ΔT and a pressure change rate threshold ΔP_{θ} are set;
the pressure change rate threshold ΔP_{θ} is determined according to an angle-rate empirical curve; wherein the angle-rate empirical curve is a curve of changes in pressure change rate inside the quartz tube with the valve opening angle under the fixed flow rate and temperature conditions;
S1, obtaining the pressure change rate ΔP over the pressure sampling interval ΔT;
S2, determining whether an absolute value of the pressure change rate ΔP exceeds the set pressure change rate threshold ΔP_{θ};
S2.1, determining a step angle and a direction of the valve according to a degree to which the absolute value of the pressure change rate exceeds the set pressure change rate threshold, as well as positive and negative values of the pressure change rate ΔP when the absolute value of the pressure change rate ΔP exceeds the set pressure change rate threshold ΔP_{θ}; and
S2.2, further acquiring a current pressure value P, and determining magnitudes of the current pressure value P and the target pressure, as well as positive or negative pressure change rate ΔP when the absolute value of the pressure change rate ΔP does not exceed the set pressure change rate threshold ΔP_{θ}; and determining the step angle and the direction of the valve; and
S3, reading and acquiring a pressure inside the quartz tube after the valve opening angle is adjusted, and calculating a difference between the acquired pressure and the target pressure, and determining whether the difference falls within an error range;
maintaining a current valve opening angle when the difference falls within the error range; or sampling a pressure change rate in a next sampling cycle when the difference fails to fall within the error range; and repeating the above process.

2. The apparatus according to claim 1, wherein the temperature system comprises a temperature sensor; the temperature sensor is disposed on an outer wall of the quartz tube at a position corresponding to a deposited sample, and the temperature sensor is configured to obtain a temperature at the position of the deposited sample in real time; and the control system is configured to adjust heating power and heating duration according to the real-time temperature feedback from the temperature sensor to ensure that a temperature inside the quartz tube reaches a target temperature value.

3. The apparatus according to claim 2, further comprising an in-situ characterization system, wherein the in-situ characterization system comprises an absorption spectrum detection device, and a spectrum movement and optical path calibration device; the absorption spectrum detection device comprises a light source, a light source emitting module, a light source receiving module, and a spectrometer connected to the light source receiving module; the spectrum movement and optical path calibration device comprises two linear guide rails, and the light source emitting module and the light source receiving module are respectively mounted on the two linear guide rails; a tubular CVD device comprises a furnace chamber, a quartz tube, and a quartz boat disposed within the quartz tube for holding the deposited sample; the furnace chamber is provided with two symmetrical optical access slots parallel to the quartz tube, the two optical access slots are symmetrically arranged with respect to an axial centerline of the quartz tube, and the two linear guide rails of the spectrum movement and optical path calibration device are respectively located at positions outside the furnace chamber corresponding to the two optical access slots, such that the light source emitting module and the light source receiving module are capable of moving linearly in an axial direction of the quartz tube to achieve online in-situ detection of samples at any position in the quartz tube; and light emitted from the light source emitting module passes through the optical access slots, traverses the quartz tube and the deposited sample inside the quartz tube, and then reaches the light source receiving module, and the received light is then analyzed by the spectrometer to achieve in-situ detection of the deposited sample.

4. The apparatus according to claim 3, further comprising a furnace chamber travel track configured to enable the movement of the furnace chamber.

5. The apparatus according to claim 4, wherein the flow rate system comprises a flow meter, and the control system is configured to control the flow meter according to preset flow rate parameters to achieve precise flow rate control.

6. The apparatus according to claim 5, further comprising a touch screen.
